(19) United States
(12) Patent Application Publication
(10) Pub. No.: US 2024/0186306 A1
(43) Pub. Date: Jun. 6, 2024

(54) Bezel-free and Infinitely High-resolution Electronic Display

(71) Applicant: Binh Tinh Tran, GRAHAM, NC (US)

(72) Inventor: Binh Tinh Tran, GRAHAM, NC (US)

(73) Assignee: Binh Tinh Tran, GRAHAM, NC (US)

(21) Appl. No.: 18/410,995

(22) Filed: Jan. 11, 2024

(51) Int. Cl. H01L 25/16; G06F 3/041; G09G 3/32

(52) U.S. Cl. CPC H01L 25/167; G06F 3/041; G09G 3/32

(57) ABSTRACT

An electronic display with a bezel-free and infinitely high-resolution display (high pixel density per inch) includes a display substrate with an array of display pixels disposed on one side of the display substrate and all or partial electrical connections that connect each pixel (including at least three subpixels: red, blue, and green micro inorganic light-emitting diodes) to power controllers, pixel controllers, etc. are placed on the other side of the substrate via holes etched into the display substrate from the front-side to the backside by either dry or wet etch, or both techniques. At least one level of the electrical circuits on the other side of the substrate can be sunk into the substrate via trenches created by the same etching mentioned above to reduce the display panel's total thickness.

### BACKGROUND OF THE INVENTION

This invention generally relates to an electronic display fabrication and particularly to a way that electrical connections connect to pixels, which can be a micro light-emitting diode, mini light-emitting diodes, or light-emitting diodes (from now on, they will all be called microLEDs), through holes made from one side to the other of the display substrate to control its operation, reduce the non-interactive border, and thin down the display thickness to have an electronic display with true-bezel-free and infinitely high-resolution.

In the last decade, mobile electronic devices have become essential for billions of people worldwide due to their valuable functions in our lives. Today, there are many different electronic displays, such as mobile electronic displays, smartwatch displays, equipment displays (displays on machines to be used as controllers), tablet personal computer displays, augmented and virtual realities (AR/VR), outdoor advertisement displays, etc. They will likely have the same display architecture, components, and fabrication process. Regardless of whether the size of the device is big, like a television without a touch screen, or small, like a smartwatch with a touch screen, the bezel of the display has been reduced over the years to have a better appearance as well as to decrease the non-interactive border, so it increases the overall display screen. It is essential for some hugely popular devices, such as smartphones, tablets, and smartwatches.

A microLED display production requires up to billions of pixels (which generally include at least red, blue, and green-color microLEDs) to be placed in an array of rows and columns on a substrate, where they are also electrically connected to pixel controllers along the rows and columns to be controlled. Due to the number of electrical connections and pixel controllers that occupy most of the area on the substrate, the bezel of the display is large. So, to minimize it, it is always desirable for any display manufacturer. Some techniques have been presented to reduce the bezel size, such as bending the border area contiguous with extending from the active area of the substantially flat surface and a plurality of traces coupled to the active area and routed in the bent border area, as presented in the granted U.S. Pat. No. 9,652,096 B2. This technique is basically not a bezel-free display itself nor an economic technique. Another dominant technique is also claimed in the granted U.S. Pat. No. 11,430,774. Each pixel in the column of pixels closest to a display substrate edge is spatially separated from the edge by a distance less than or equal to the column distance. At least one row pixel controller is spatially separated from the corresponding row by a distance less than the column or row distance; at least one column pixel controller is spatially separated from the corresponding column by a distance less than the column or row distance. Generally, this is like redistributing the electrical connections on the display substrate since the fundamental issues still need to be solved. Major electrical connections still occupy the display substrate surface, and pixel controllers and the number of pixels are still minor. The large bezel and low-resolution displays are still present. Therefore, a new doable technique to have a true-bezel-free and infinitely high-resolution display is necessary to remove the non-interactive border, increasing the display area to have a better appearance device such as a smartphone without increasing the overall size.

### SUMMARY OF THE INVENTION

The technique is related to reducing the display's bezel from near-bezel-free to true-bezel-free and leading to an infinitely high-resolution electronic display. Therefore, the non-interactive border of any electronic device goes to zero bezel. The substrate (silicon, glass, flexible film, or any material that can be used as a display substrate) that can be used to place the microLED pixels on it will be deeply etched from one side through another via dry or wet etch or both etch methods, or any method. The etch method will create a circle, rectangular, or any shape hole that will be used to move the electrical connections from a surface side to another side of the substrate. Therefore, the substrate's surface will have much more room to place more pixels anywhere within the substrate. The pixels, electrical connections, and pixel controllers can now be disposed of separately on two different surface sides of a substrate. In some embodiments, as discussed in detail below, the manufacturing process will create different scenarios from near-bezel-free to true-bezel-free with infinitely high-resolution.

### BRIEF DESCRIPTION OF THE DRAWINGS

FIG. 1 is a typical illustration of a single microLED pixel connected to a pixel controller with many electrical connections placed on one side of a display substrate.

FIG. 2 A process to create a hole on the display substrate.

FIG. 3a is a 3D view of a hole created from one side to the other side of the display substrate via dry or wet etch or both techniques.

FIG. 3b a 3D cross-sectional view of the hole with a neck somewhere between two sides of the display substrate

FIG. 3c is a 3D cross-sectional view of the hole created with a scalloped sidewall inside the hole instead of a neck.

FIG. 3d the backside of the display substrate where the pixels are not placed. Trenches can be created to bury at least one level of the electrical connection.

FIG. 4a this embodiment shows partial electrical connections and other components moved from the front-side to the backside of the substrate display.

FIG. 4b the display substrate in this embodiment, has more room to dispose of pixels on the front-side of the display substrate.

FIG. 5a this embodiment shows all or partial electrical connections and other components moved to the backside of the substrate display. Holes are created underneath the p-type microLEDs.

FIG. 5b the display substrate in this embodiment has much more room to dispose of pixels on the front-side of the display substrate with bezel-free at all edges.

FIG. 6a this embodiment shows all electrical connections wired from p and n types of microLEDs directly to the backside of the display substrate. Other components are also moved to the backside of the display substrate.

FIG. 6b the substrate display in this embodiment is fully covered with pixels. The bezel is truly free, and the electronic display has an infinitely high-resolution.

### DETAILED DESCRIPTION OF THE INVENTION

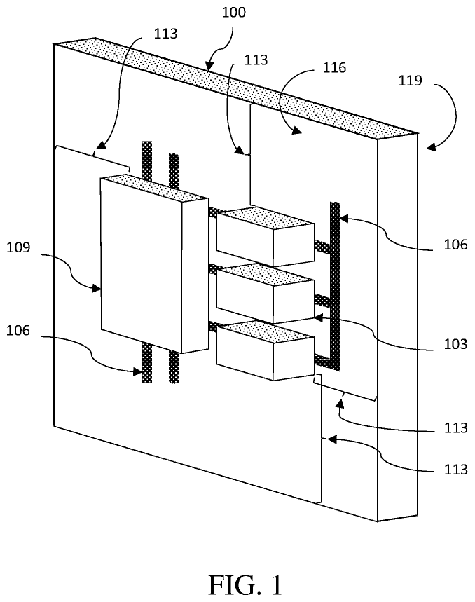

The following embodiments of this invention provide a near-bezel-free and true-bezel-free microLED electronic display. Any current microLEDs have many pixels 103 with different sizes and pitches within a display substrate surface with many pixel controllers 109 and electrical connections 106 403 along the columns and rows in an array. Those pixel controllers 109 and electronic connections 106 403 are located between microLEDs and along the display edge 113 of the display substrate 100, as shown in FIG. 1.

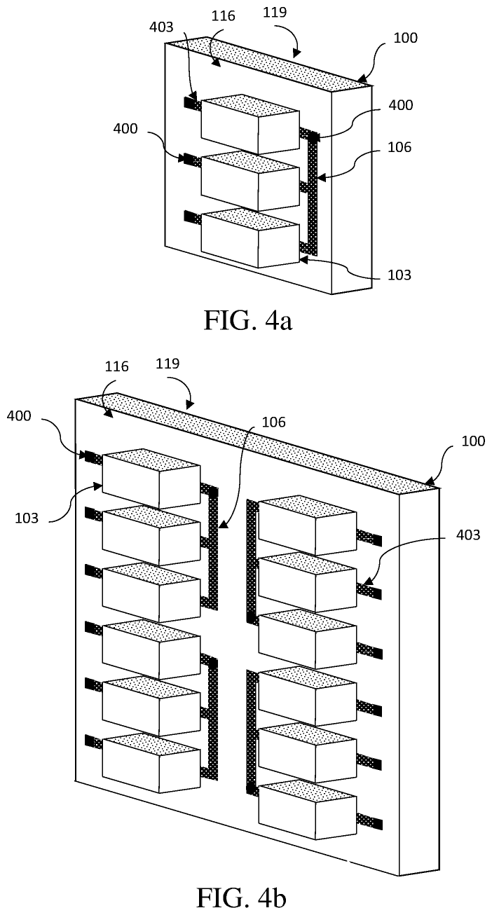

Referring to the 3D plan view of FIG. 1 (all figures presented in this invention are not to scale). According to some embodiments of this invention, a bezel-free electronic display comprises a display substrate 100, electrical connections 106 403 pixel controllers 109, and two or more bezel edges 113. A display substrate 100 can be a rectangular surface, as shown in FIG. 1, with four edges and two faces 116 119 (front and backsides). According to some embodiments of this present invention, all edges will have near-bezel-free or true-bezel-free edges, as shown in FIG. 4b, 5b, 6b.

As shown in FIG. 1, a pixel combines of the usual three subpixels, red, blue, and green-color microLEDs 103. Pixels are disposed on a display substrate 100 in an array of columns (vertically) and rows (horizontally) from edge to edge. As shown in the illustrative example in FIG. 1, a display substrate 100 can have a shape with two or more edges. Regardless of the shape, column pixels are disposed vertically, and row pixels are disposed horizontally at the edges 113 of the display substrate 100. The pixel pitch or pixel separation in the column equals the pixel pitch or pixel separation in the row in an array on the electronic display substrate 100.

According to certain embodiments of the present invention, the row and column distances of pixels can be larger than a subpixel pitch, equal to a subpixel pitch or less in the directions of the rows and columns, or the row and column distance, respectively. A subpixel pitch is the distance from the center of one subpixel to an equivalent point of an adjacent subpixel.

A microLED electronic display with an array of pixels disposed vertically and horizontally is a display substrate 100 with two faces (front and back sides). It is usually a rectangular display shape 100 with pixels disposed in rows and columns on all four edges 113 to cover the whole display substrate 100 on one side 116 and all or partial other components, such as electrical connections 106 403 and pixel controllers 109, to the display on the other side.

Each pixel disposed on the electronic display substrate, as shown in FIG. 1, comprises at least one microLED or subpixel 103 containing a diode structure independently, separately, and distinct from the display substrate 100. Thus, each subpixel or microLED is mounted individually on the display substrate 100 by different techniques, for example, micro-transfer printing, stamp transfer technology, or laser printing. Pixels, including subpixels, can include electrical connections 106 403 from subpixels 103 to pixel controllers 109, power controllers, and the ground (not shown here) that all provide the power to the subpixels 103 to emit lights based on the input and output signals.

FIG. 1 shows a representative common electronic display substrate 100 with a single pixel in which all electrical connections, such as row and column lines, power lines (not shown here), and pixel controllers 109, are disposed on a single side of the display substrate 100. A typical pixel is one in which each subpixel 103 is connected to a pixel controller 109 and ground line (an electrical connection) 106. All electrical connection lines can be formed on a display substrate 100 using some standard techniques, such as mask aligner photolithography, direct laser writing, printed-circuit board processing, or electron beam lithography with a positive or negative, or poly methyl methacrylate photoresist coated and patterned it before suitable metals can be deposited onto it by using an electron beam evaporation, sputter deposition, electrochemical deposition, chemical vapor deposition, atomic layer deposition, or thermal oxidation method. All metal structures and the display substrate (silicon, glass, quartz, flexible film substrate, or whatever can be used as a display substrate) can be formed via dry and/or wet etch techniques. As shown in FIG. 1, the electrical connections 106 and a pixel controller 109 used to control at least one pixel can occupy a large area. For a complete display substrate, they will occupy a significant portion of the front-side 116 of the display substrate 100; therefore, the bezel 113 of the electronic display substrate is large, and the final electronic display has a low resolution. More details regarding how to suppress the electrical connections are provided below.

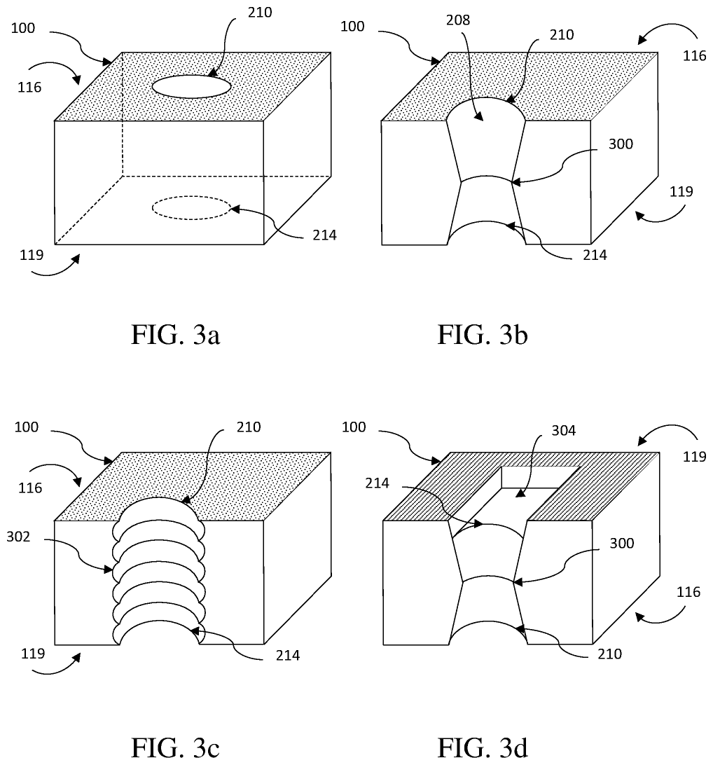

FIG. 3a provides a portion of the front-side view of the 3D display substrate 100, where a representative single hole is created from the front 116 to the backside 119 of the display substrate 100. This hole can be circular, triangular, square, or any other shape. The details of making these holes will be presented in the following.

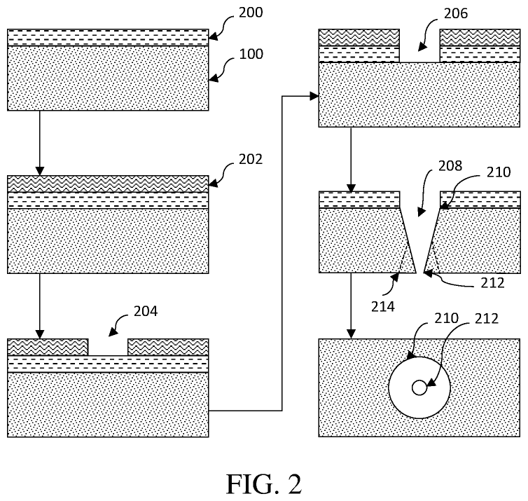

In certain embodiments, the display substrate 100 can be silicon, glass, quartz, flexible film substrate, or any material used to dispose of the microLEDs 103. On the top of the display substrate 100, a SiNₓ, SiO₂, polyimide, or metal 200 is deposited to cover the whole surface of the display substrate 100, as shown in FIG. 2, to be used as a mask to etch the display substrate 100, and then a positive or negative photoresist or a poly methyl methacrylate photoresist 202 will be later coated to pattern by a photomask aligner, direct laser writing, auto stepper, or electron beam lithography to pattern and etch the SiNₓ, SiO₂, polyimide, or any materials as mentioned above 200. The display substrate 100 with photoresist on it will then be developed to reveal the holes 204 and be used to etch the SiNₓ, SiO₂, polyimide, or any materials 200 deposited prior to the photoresist coating. As mention above, the SiNₓ, SiO₂, polyimide, or any coated materials can be etched 206 by dry etching, such as reactive-ion etching, chemical wet etching, or both techniques, depending on the purpose. The photoresist layer can be stripped away after SiNₓ, SiO₂, polyimide, or any materials mentioned are etched 206, and before the display substrate can be etched by using acetone, isopropanol, gamma-butyrolactone, remover PG, Microposit remover 1165, or whatever can be used to remove the photoresist. Ultrasonic and plasma descum can also be applied to remove the photoresist completely. SiNₓ, SiO₂, polyimide, or any materials as mentioned above with an array of holes in rows and columns are now available to etch the display substrate 100 via dry etch, such as reactive-ion etching, deep reactive-ion etching, chemical wet etch, or both techniques, or wet etch, or whatever technique depends on the purpose. The first anisotropy etches of the display substrate can dig holes 208 through the backside 119 of the display substrate 100 or stop somewhere close to the backside surface 119. When performing the second anisotropy, if the first etch got through the backside of the display substrate, those tiny holes 212 that were just opened on the backside of the display substrate will be used to align to create the holes from the backside 119 back to the front-side 116 of the display substrate with an identical diameter 214 to the first hole 210. If not, a mask aligner system can use the backside exposure technique to pattern the backside 119 of the display substrate. In the second anisotropy etching from the backside 119 to the front-side 116 direction of the display substrate 100, the process is the same as when the front-side of the display substrate was etched, as shown in FIG. 2. But the etching time on the front and back sides may differ. Finally, as mentioned above, the SiNₓ, SiO₂, polyimide, or any coated materials can be etched away after the holes are created using hydrofluoric acid, buffered oxide etch, or reactive-ion dry etching.

The holes 208 created this way on the display substrate will have a neck 300 somewhere between the front 116 and backside 119 surfaces of the display substrate 100, as shown in FIG. 3b. In certain embodiments, other solutions can replace the neck, such as creating a scalloped sidewall 302 inside the holes 208, as shown in FIG. 3c, by the reactive-ion etching technique or deep reactive-ion etching. Metals that can be used to form the electrical connections 106 303 will later fill the holes 208, and the holes will become connections with metals inside to directly connect the p and n contacts of each subpixel microLED to other components, such as pixel controllers 109. The holes 210 214, with a neck 300 or a scalloped sidewall 302, will hold the electrical connections tightly inside the holes to avoid them slipping out of the front 116 or backside 119 of the display substrate 100.

FIG. 3d provides a representative cross-sectional view of the hole 208 created on the display substrate 100. In certain embodiments, on the backside 119, all or partial electrical connections from the p and n types of subpixels are moved from the front 116 to the backside 119 of the display substrate 100 and are disposed of there together with other components, such as pixel controllers 109, to leave a maximum area to dispose of as many pixels as possible on the front-side 116. On the backside, which contains a complementary metal-oxide-semiconductor structure on the backside. To thin down the total thickness of the electronic display, at least one layer of the complementary metal-oxide-semiconductor can be buried into the backside of the display substrate. FIG. 3d shows the backside of the display substrate 119 and the backside of the holes 214 with a trench 304 that has been created. That trench 304 can also apply to other electrical connections as well. The metals deposited to fill the holes 208 on the backside 119 can also fill the trench 304 at the same time if the trench is needed to thin down the electronic display. That means at least one layer of the complementary metal-oxide-semiconductor will be buried.

FIG. 4a shows a representative front-side view of the 3D electronic display substrate 100 with a single pixel on it. In certain embodiments, the three or more n types of all subpixels 103 of a pixel are connected 106 and wired through holes 400 to connect with the electrical connections in the backside 119 of the display substrate 100. In this case, the n-type electrical connections 106 of all subpixels of a pixel are visible, as shown in FIG. 4a. Meanwhile, those of p types of all subpixels of a pixel are not connected intentionally. Their p-type electrodes are placed on a terminal of the short electrical connections 403, and the other terminal of those electrical connections is wired through the holes 400 to connect them with the electrical connections on the backside 119 of the display substrate 100, similar to the n-type case. Those n and p types are later connected to other components, which were moved from the font 116 to the backside 119 of the display substrate as compared to all current standard fabrications.

The short electrical connections on the front 403 of the display substrate 100 can be formed after the holes are created and metals are filled up. They are formed using either a negative or positive photoresist priority for lithography exposure by a mask aligner, direct laser writing, electronic beam lithography technique, or other photolithography techniques. SiNₓ, SiO₂, or polyimide may be omitted because the metals can be deposited directly on the display substrate after exposure to a photoresist mask. The metals will then be deposited on the front surface 116 of the display substrate 100 by electron beam evaporation, sputtering, and lift-off to reveal the individual electrical connection. The electrical connections of all p types that were wired to the backside 119 of the display substrate 100 will be connected to the complementary metal-oxide-semiconductor, which includes multi-level electrical connections. That is how to minimize the electrical connections and other components, such as pixel controllers 109 on the front-side 116 of the display substrate 100, to have a near-bezel-free or true-bezel-free electronic display with high- or infinitely high-resolutions, respectively.

In this embodiment, partial components such as pixel controllers 109 are moved to the backside of the display substrate 100. The electrical connections from the p or n types of all subpixels or all electrical connections of all p and n types are also moved to the backside of the display substrate to connect to the pixel controllers and other components, as shown in FIG. 4a. In addition, FIG. 4b shows an embodiment where all or partial pixel controllers 109 are moved to the backside of the display substrate 100. The electrical connections 106 403 of a pixel (of at least three subpixels) are also moved to the backside of the display substrate 100. On the front-side 116 of the display substrate, there are now more rooms to dispose of the pixels. The number of pixels on the display substrate is now higher density if we compare it to a display substrate using a standard fabrication that includes a complementary metal-oxide-semiconductor, as shown in FIG. 1. In this case, the electronic display has a smaller bezel and a higher resolution display.

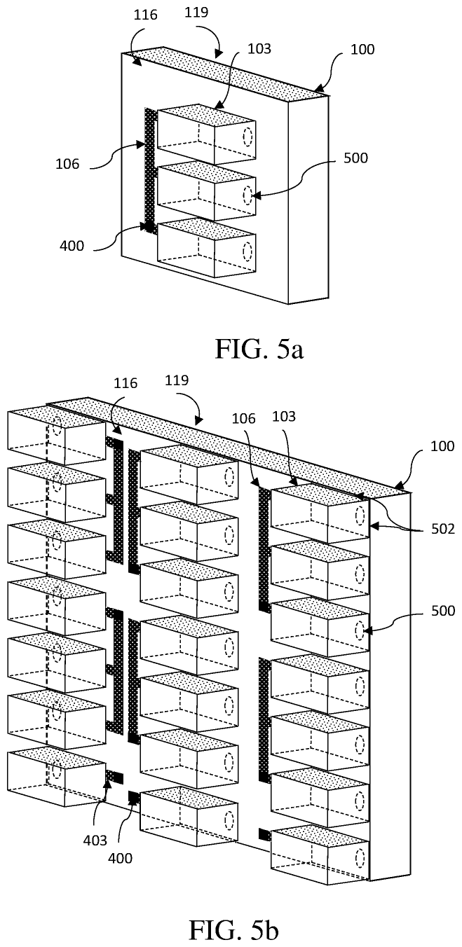

FIG. 5a provides a representative front-side view of the 3D electronic display substrate with a single pixel disposed on the display substrate 100. In certain embodiments, the microLEDs can be disposed of using popular techniques such as stamp pick and place, self-assembly, selective release, or roll printing. The n-type contacts of each pixel's subpixels are connected 106 and wired to the backside of the display substrate 100 via a hole 400 made by dry or wet etch or both, as mentioned above. The p contacts of all subpixels are placed directly on the top of the holes 500 where the metals have filled up the holes. Therefore, not all electrical connections are seen at the p types of all subpixel devices.

FIG. 5b shows the electronic display substrate 100 with all n-type contacts showing electrical connections 103 403 remaining. Still, all p-type contacts do not show any electrical connections since they are wired directly to the electrical connection underneath 500 through the backside 119 of the display substrate 100.

In this embodiment, regardless of how many percentages of the other components are disposed of on the front-side 116 as well as on the backside 119 of the display substrate 100, the front-side 116 of the display substrate still has much more room to dispose of the microLEDs as compared to the embodiment as shown in FIG. 4b. If all other components, such as pixel controllers 109, are moved to the backside of the display substrate, the electronic display resolution in this embodiment is now at another high level because there are likely no dead regions (i.e., regions to place electronic connections and other components). In this case, the bezel of the electronic display substrate is therefore bezel-free 502 since all the pixels are possibly disposed right at the edge 113 of the display substrate 100, as shown in FIG. 5b, and has a very high-resolution electronic display.

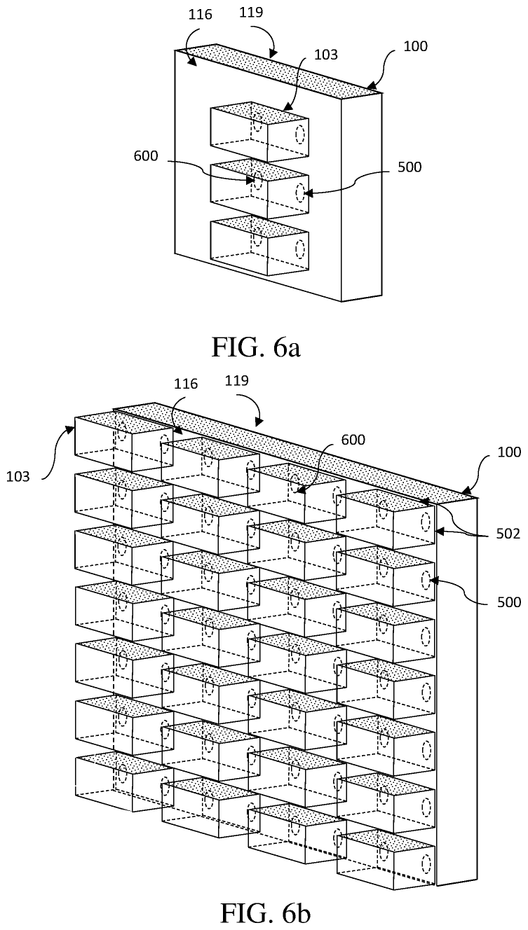

FIG. 6a provides a representative front-side view of the 3D electronic display substrate with a single-pixel disposal on the display substrate. In this embodiment, all electrical connections 106 403 are moved to the backside 119 of the display substrate 100, including other components such as pixel controllers 109. Similar to the embodiment of FIG. 5(a-b), all p types of subpixels in this embodiment are wired directly from the microLED dies 103 to the backside 119 of the display substrate 100 from underneath each pixel via the holes 600 and connected to other components. In this embodiment, two holes 500 600 will be created underneath each subpixel to wire each subpixel's p- and n-type contacts from the front 116 to the backside 119 of the display substrate 100. However, too many holes can make the substrate fragile, and it also depends on the material of the display substrate. To suppress this issue, a trench 304 can be created underneath all n pixel types to connect all n types of subpixels. Therefore, only one hole is needed for all n types of subpixels of a pixel. Either way, the bezel 113 of the electronic display substrate in this embodiment is, therefore, true-bezel-free 113. Since all the pixels are disposed right at the edge 502 of the display substrate 100, as shown in FIG. 6b. In this embodiment, all subpixels and pixels have the lowest pitch distance, and therefore, the display resolution of the electronic display substrate is infinitely high. The pixel and subpixel pitches vary depending on the purpose of the display, whether it is transparent or fully covered with pixels on the display substrate to have the maximum display resolution.

What is claimed:

1. A bezel-free, high- or infinitely high-resolution electronic display comprising:
A substrate display has any shape, like a square, rectangular, triangle, hexagon, or irregular shape, with or without any cut-out on two sides (front and back sides). A substrate display may have two (half-moon) or more bezel edges.
On the front-side of the display substrate, all pixels are disposed in arrays in columns and rows with a distance between column and row pixels of different spacings for different embodiments, from larger, equal, to smaller than the width of each subpixel. Subpixel pitch can be larger, equal, or smaller than the width of each subpixel. Each pixel comprises at least three subpixels of red, blue, and green-color microLEDs (including mini-LEDs and LEDs), developed using groups III and V semiconductor materials such as GaN, AlN, InN, and GaAs.
On the back side of the display substrate, all or partial electrical columns, row lines, and other electrical lines are disposed in either a vertical or horizontal direction. Those electrical connections are connected to the pixels on the front-side of the display substrate via holes created through the display substrate. They are then connected to other components like pixel and power controllers.

2. The bezel-free, high- or infinitely high-resolution electronic display defined in claim 1, wherein a partial column and row of electrical connections, as well as partial other electrical connections and components such as pixel controllers, are disposed on the front-side of the display substrate with all microLED pixels.

3. The bezel-free, high- or infinitely high-resolution electronic display defined in claim 1, wherein only a partial column and row of electrical connections and/or partial pixel controllers are disposed on the front-side of the display substrate together with all microLED pixels.

4. The bezel-free, high- or infinitely high-resolution electronic display defined in claim 1, wherein a partial pixel controller is disposed on the front-side of the display substrate with all microLED pixels.

5. The bezel-free, high- or infinitely high-resolution electronic display defined in claim 1, wherein only microLED pixels are disposed on the front-side of the display substrate

6. The bezel-free, high- or infinitely high-resolution electronic display defined in claim 1, wherein all or partial electrical connections that are connected directly to the p and n types of the microLEDs are moved to the backside of the display substrate through holes made by dry or wet etching or both or any other techniques.

7. The bezel-free, high- or infinitely high-resolution electronic display defined in claim 1, wherein one or more holes with one or more necks somewhere inside the hole or a scalloped sidewall inside, made from one side (i.e., the front-side) to the other side (i.e., the backside) of the display substrate by wet or dry etching or both or any other techniques and filled with metals by an electron beam evaporator, sputtering or both or any techniques to spread the current from, for example, the power source to pixels to control them from the backside.

8. The bezel-free, high- or infinitely high-resolution electronic display defined in claim 1, wherein any electrical connections are moved from one side (i.e., the front-side) to the other side (i.e., the backside) of the display substrate through holes (of any shape and size) made by wet or dry etching or both or any other techniques.

9. The bezel-free with high- or infinitely high-resolution electronic display defined in claim 1, wherein any electrical connections and components are not disposed of on the front-side, which will be disposed of on the backside of the electronic display substrate.

10. The bezel-free, high- or infinitely high-resolution electronic display defined in claim 1, wherein all pixel controllers can be disposed of on either the front or backside of the electronic display substrate.

11. The bezel-free with high- or infinitely high-resolution electronic display defined in claim 1 further may comprise a touch sensor substrate.

12. The bezel-free with high- or infinitely high-resolution electronic display defined in claim 1, wherein the subpixel and pixel pitches are varied. They can be at a minimum distance but not touch each other.

13. The bezel-free with high- or infinitely high-resolution electronic display defined in claim 1, wherein how many percentages of the other components, such as pixel controllers, are disposed on the front-side is dependent on the required electronic display resolution.

14. The bezel-free, high- or infinitely high-resolution electronic display defined in claim 1 wherein the pixel pitches are varied to have different transparencies.

15. The bezel-free with high- or infinitely high-resolution electronic display defined in claim 1, wherein the pixel pitches are varied, which depends on the substrate materials to have a rigid or flexible electronic display substrate.

16. The bezel-free with high- or infinitely high-resolution electronic display defined in claim 1, wherein the resolution of the electronic display can be as high as the downsizing of the microLEDs, the number of electrical connections moving to the backside of the display substrate, and the subpixels and pixels pitches.

17. The bezel-free, high- or infinitely high-resolution electronic display defined in claim 1, wherein all or partial electrical connections on the backside of the display substrate are buried below the surface.

18. The bezel-free with high- or infinitely high-resolution electronic display defined in claim 1, wherein at least one electrical connection level is buried below the surface of the display substrate in either the front or backside of the display substrate

19. The bezel-free, high- or infinitely high-resolution electronic display defined in claim 1, wherein a partial thickness (i.e., the thickness of the microLED substrate, which is usually a sapphire, Si, or GaAs) of the microLEDs can be buried below the surface of the display substrate.

20. The bezel-free, high- or infinitely high-resolution electronic display defined in claim 1, wherein all or partial electrical connections and pixel controllers are disposed of on the backside of the display substrate and further connected to secondary substrates.
